(19) United States
(12) Patent Application Publication
(10) Pub. No.: US 2016/0088198 A1
(43) Pub. Date: Mar. 24, 2016

(54) ACTUATOR UNIT AND CAMERA MODULE INCLUDING THE SAME

(71) Applicant: SAMSUNG ELECTRO-MECHANICS CO., LTD., Suwon-Si (KR)

(72) Inventors: Bok Sun AN, Suwon-Si (KR); Sang Hyo Seo, Suwon-Si (KR); Kyung Hun Lee, Suwon-Si (KR)

(73) Assignee: SAMSUNG ELECTRO-MECHANICS CO., LTD., Suwon-Si (KR)

(21) Appl. No.: 14/568,110

(22) Filed: Dec. 12, 2014

(30) Foreign Application Priority Data
Sep. 19, 2014 (KR) 10-2014-0125158

(51) Int. Cl. H04N 5/225; H05K 1/18; G02B 7/04; G03B 13/34; H01L 41/047

(52) U.S. Cl. CPC H04N 5/2252; G03B 13/34; H01L 41/0472; H01L 41/0471; G02B 7/04; H05K 1/189; H04N 5/2257; H04N 5/2254

(57) ABSTRACT

There is provided an actuator unit including: a support member supporting a first lens so that the first lens is maintained in a non-contact state with a second lens adjacent thereto; and a piezoelectric member connected to the support member, deforming the support member so that the lenses are movable in an optical axis direction, and including a plurality of piezoelectric elements and a plurality of internal electrodes. The actuator unit configured as described above may improve driving reliability of the lens.

### CROSS-REFERENCE TO RELATED APPLICATION

This application claims the priority and benefit of Korean Patent Application No. 10-2014-0125158 filed on Sep. 19, 2014, with the Korean Intellectual Property Office, the disclosure of which is incorporated herein by reference.

### BACKGROUND

The present disclosure relates to an actuator unit adjusting a focal length of a lens, and a camera module including the same.

A high resolution camera apparatus includes a plurality of lenses and an image sensor. Such a camera apparatus may include a moving means moving a lens barrel in an optical axis direction in order to capture a clear image.

However, since such a structure moves the lens barrel, an apparatus element having significant mass, to adjust a focal length of lenses, a current consumption amount may be relatively high and a structure of the moving means may be relatively complicated, both of which are disadvantageous in terms of miniaturizing camera apparatuses.

For reference, Patent Documents 1 and 2 are provided as related art.

### RELATED ART DOCUMENT

(Patent Document 1) KR2005-042922 A

(Patent Document 2) KR2008-001992 A

### SUMMARY

An aspect of the present disclosure may provide an actuator unit having improved driving reliability and a camera module having a simple assembly feature.

According to an aspect of the present disclosure, an actuator unit may include: a plurality of piezoelectric elements having a first size; and a plurality of internal electrodes having a second size.

According to another aspect of the present disclosure, a camera module may include: an actuator unit configured to move one or more lens; and a connecting unit formed on a housing and connected to the actuator unit.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a camera module according to an exemplary embodiment of the present disclosure;

FIG. 2 is an assembled perspective view of the camera module shown in FIG. 1;

FIG. 3 is a cross-sectional view of a lower housing taken along line A-A of FIG. 2;

FIG. 4 is a cross-sectional view of an actuator unit shown in FIG. 2;

FIG. 5 is an exploded perspective view of a piezoelectric member shown in FIG. 4;

FIG. 6 is an assembled perspective view of the piezoelectric member shown in FIG. 5;

FIG. 7 is a cross-sectional view of the piezoelectric member taken along line B-B of FIG. 6;

FIG. 8 is an assembled perspective view of a piezoelectric member according to another form;

FIG. 9 is a cross-sectional view of the piezoelectric member taken along line C-C of FIG. 8;

FIG. 10 is a cross-sectional view of the camera module shown in FIG. 2;

FIG. 11 is an exploded perspective view of a camera module according to another exemplary embodiment of the present disclosure;

FIG. 12 is an assembled perspective view of the camera module shown in FIG. 11; and

FIG. 13 is a cross-sectional view of the camera module shown in FIG. 12.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

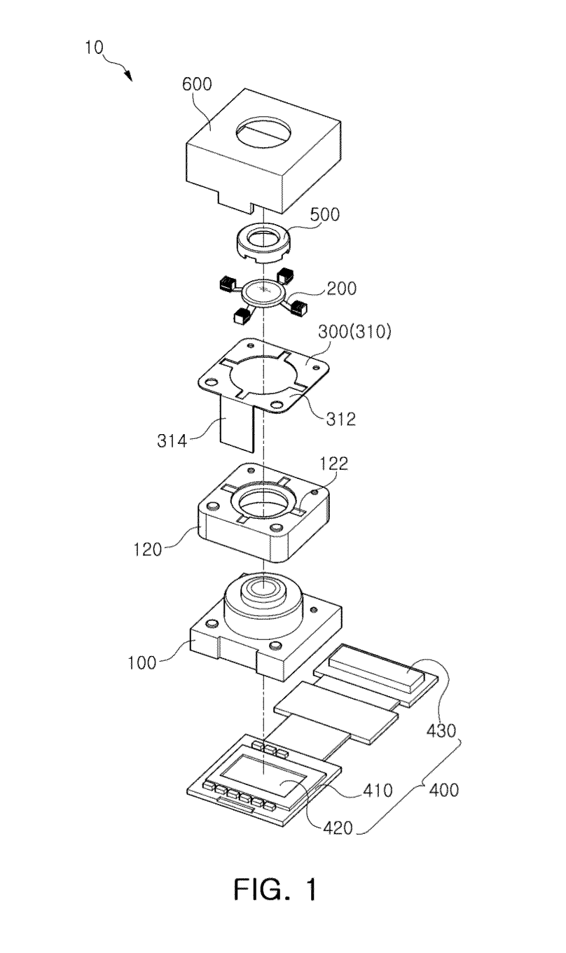

A camera module according to an exemplary embodiment of the present disclosure will be described with reference to FIG. 1.

The camera module 10 may include a housing unit 100, an actuator unit 200, and a connecting unit 300. In addition, the camera module 10 may further include an image sensor unit 400, a cover member 500, and a shield can 600. The camera module 10 configured as described above may be mounted in a portable terminal such as a mobile phone, a portable computer, or the like.

The housing unit 100 may be configured to accommodate one or more lens therein. For example, the housing unit 100 may have a space formed therein in order to accommodate a plurality of lenses therein. The housing unit 100 may be divided into two or more members. For example, the housing unit 100 may be configured of a lower housing 110 and an upper housing 120.

The lower housing 110 may be configured to accommodate the lens therein. For example, the lower housing 110 may be provided with an accommodation space in which one or more lens may be mounted. For reference, the accommodation space may be widened in a direction from the top of the lower housing 110 toward the bottom thereof. The lower housing 110 may be formed so that upper and lower surfaces thereof are open. For example, the upper surface of the lower housing 110 may be open so that light reflected from a subject may be incident therethrough, and the lower surface of the lower housing 110 may be open so that light refracted by the lens is projected onto an image sensor therethrough.

The upper housing 120 may be coupled to the lower housing 110. For example, the upper housing 120 may be coupled to an upper portion of the lower housing 110. The upper housing 120 may form a space in which the actuator unit 200 may be mounted. For example, an upper portion of the upper housing 120 may be provided with a seating part 122 for the actuator unit 200.

The housing unit 100 configured as described above may be coupled to the image sensor unit 400.

The actuator unit 200 may be mounted on the housing unit 100. For example, the actuator unit 200 may be mounted on the seating part 122 of the upper housing 120. The actuator unit 200 may be configured to perform an auto-focusing operation. For example, the actuator unit 200 may move one or more lens in an optical axis direction. The actuator unit 200 may include a lens 210, a support member 220, and a piezoelectric member 230. For example, the actuator unit 200 may include one or more lens 210 required for focusing, a plurality of support members 220 supporting the lens 210, and a plurality of piezoelectric members 230 generating warpage deformation of the support members 220.

The actuator unit 200 configured as described above may move the lens 210 toward the subject (that is, in an upward direction based on FIG. 1) or move the lens 210 toward the image sensor (that is, in a downward direction based FIG. 1) depending on a magnitude and a direction of the warpage deformation of the support member 220 by the piezoelectric member 230.

The connecting unit 300 may be formed on the housing unit 100. For example, the connecting unit 300 may be formed on a side surface of the lower housing 110 and an upper surface and a side surface of the upper housing 120. The connecting unit 300 may include a first connecting part 312 and a second connecting part 314. The first connecting part 312 may be formed on the upper surface of the upper housing 120, and the second connecting part 314 may be formed on a side surface of the housing unit 110 and 120, collectively denoted by 100. The connecting unit 300 may be configured to connect the actuator unit 200 and the image sensor unit 400 to each other. For example, the connecting unit 300 may electrically connect the actuator unit 200 and the image sensor unit 400 to each other so that the actuator unit 200 is operated by a control signal of the image sensor unit 400. The connecting unit 300 may be a flexible printed circuit board (FPCB). For example, the connecting unit 300 may be manufactured in a film form.

The image sensor unit 400 may be coupled to the housing unit 100. For example, the image sensor unit 400 may be coupled to the lower housing 110. The image sensor 400 may include a printed circuit board 410, an image sensor 420, and a connecting terminal 430. For example, the image sensor unit 400 may be manufactured in a form in which the image sensor 420 and the connecting terminal 430 are mounted on the printed circuit board 410. The image sensor 420 may be configured to convert an image projected there onto into an electrical signal. For example, the image sensor 420 may include devices such as a charge coupled device (CCD), a metal oxide semiconductor field effect transistor (MOSFET), and the like. The connecting terminal 430 may be configured to connect the camera module 10 to an external apparatus. For example, the connecting terminal 430 may include a transmitting terminal configured to transmit an image electrical signal of the camera module 10 and a receiving terminal configured to transfer an external control signal to the camera module 10. The printed circuit board 410 may be configured to connect the image sensor 420 and the connecting terminal 430 to each other. For example, the printed circuit board 410 may have circuit patterns formed thereon so as to connect the image sensor 420 and the connecting terminal 430 to each other. In addition, the printed circuit board 410 may be configured to connect the image sensor 420 and the actuator unit 200 to each other. For example, the printed circuit board 410 may include circuit patterns configured to drive the actuator unit 200 depending on a control signal transmitted from the image sensor 420.

The cover member 500 may be coupled to the actuator unit 200. For example, the cover member 500 may be coupled to the actuator unit 200 to prevent the lens 210 from being separated from the actuator unit 200. The cover member 500 may be omitted if necessary. For example, in the case in which the lens 210 and the support member 220 may be firmly attached to each other, the cover member 500 may be omitted.

The shield can 600 may be coupled to the housing unit 100. For example, the shield can 600 may be coupled to the housing unit 100 in a form in which the housing unit 100 is accommodated therein. The shield can 600 formed as described above may protect the camera module 10 from harmful electromagnetic radiation. In addition, the shield can 600 may prevent harmful electromagnetic radiation generated by the camera module 10 having a negative effect on peripheral apparatuses.

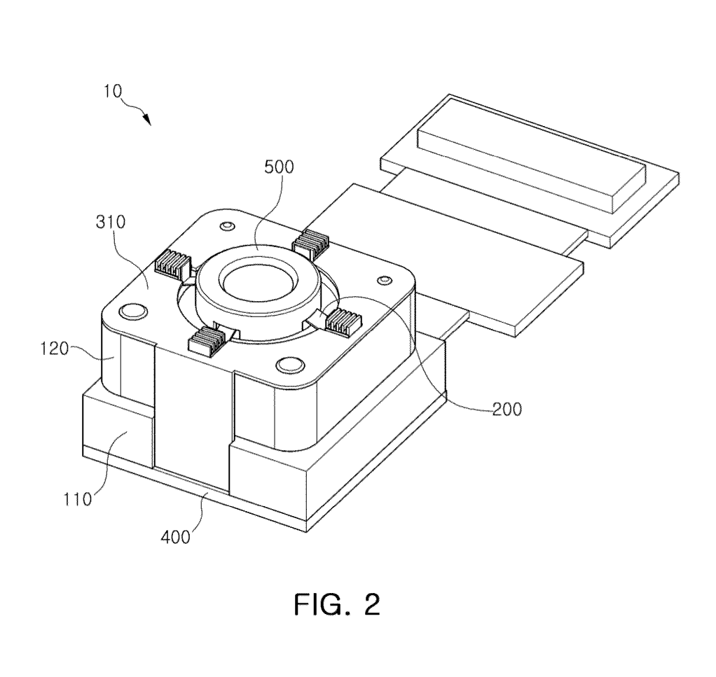

A coupling form of the camera module will be described with reference to FIG. 2 (for reference, the shield can is omitted in FIG. 2).

The camera module 10 may be formed by coupling the housing unit 100, the actuator unit 200, the connecting unit 300, the image sensor unit 400, and the cover member 500 to each other. For example, the camera module 10 may be configured in a form in which the image sensor unit 400 is coupled to a lower portion of the housing unit 100 and the actuator unit 200 and the cover member 500 are coupled to an upper portion of the housing unit 100. The connecting unit 300 may be configured in a form in which a portion thereof is formed on the upper portion of the housing unit 100 and the remaining portions thereof are extended to the lower portion of the housing unit 100 through the side surface of the housing unit 100.

In the camera module 10 configured as described above, since the connecting unit 300 connecting the actuator unit 200 and the image sensor unit 400 to each other is disposed outside of the housing unit 100, the camera module 10 may be easily assembled.

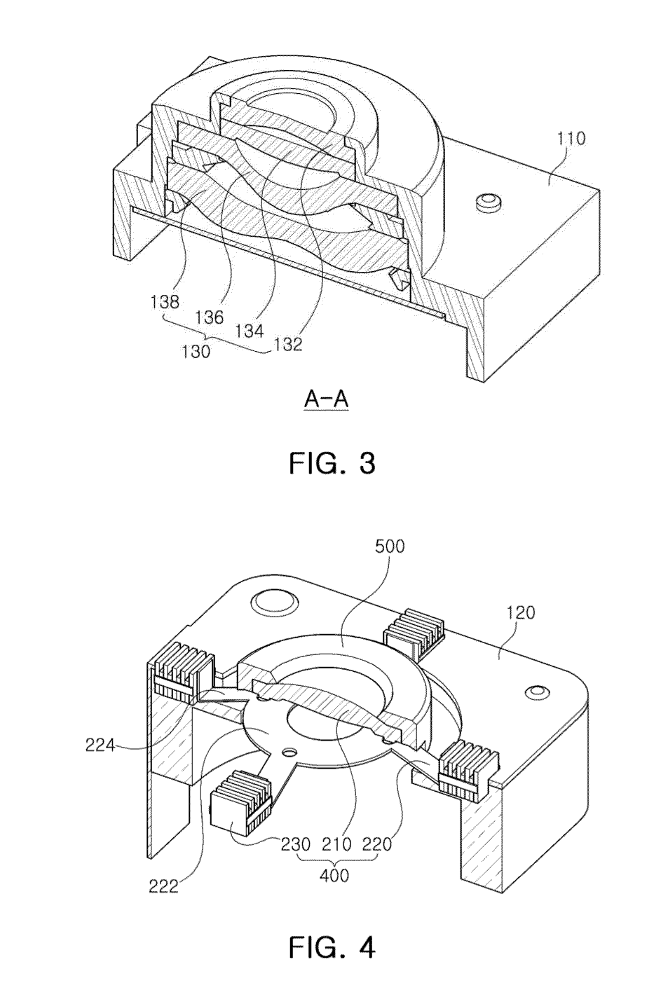

A cross-sectional form of the lower housing 110 will be described with reference to FIG. 3.

The lower housing 110 may accommodate one or more lens 130 therein. For example, four or more lenses 132, 134, 136, and 138, collectively denoted by 130, may be accommodated in the lower housing 110. However, the number of lenses accommodated in the lower housing 110 is not limited to four. For example, five or more or three or less lenses may be accommodated in the lower housing 110.

The lower housing 110 may have steps formed on an inner surface thereof. For example, the number of steps formed on the inner surface of the lower housing 110 may correspond to that of lenses 130. The steps formed as described above may serve to enable the lenses to be accurately disposed (or mounted) depending on sizes of the lenses and to align optical axes of the lenses 130 with each other.

The actuator unit will be described with reference to FIG. 4.

The actuator unit 200 may be disposed on the upper housing 120. For example, the actuator unit 200 may be disposed on one surface (upper surface based on FIG. 4) of the upper housing 120. The actuator unit 200 may include one or more lens 210, the support member 220, and the piezoelectric member 230. Hereinafter, the lens 210, the support member 220, and the piezoelectric member 230 configuring the actuator unit 200 will be described in detail.

The lens 210 may be a lens having the largest effect on adjusting a focal length of the camera module 10. For example, the lens 210 may be a lens disposed so as to be the closest to a subject side among lenses configuring an optical system of the camera module 10. The lens 210 may also be a lens having the greatest refractive power among the lenses configuring the optical system of the camera module 10. For reference, although the case in which only one lens is formed in the actuator unit 200 has been shown in FIG. 4, two or more lenses may be formed in the actuator unit 200 in order to adjust a focal length if necessary.

The support member 220 may be configured to support the lens 210. For example, the lens member 220 may be configured so that the lens 210 may move in the optical axis direction. The support member 220 may include a lens supporting part 222 and a deformed part 224. For example, the support member 220 may include the lens supporting part 222 configured to support the lens 210 and the deformed part 224 warpage-deformed so that a position of the lens 210 is changed. The lens supporting part 222 may have a form in which it supports only a flange part of the lens 210. For example, the lens supporting part 222 may have an annular shape in which a hole corresponding to an effective diameter part of the lens 210 is formed therein. The deformed part 224 may have a form in which it is substantially extended from the lens supporting part 222 in a radial direction. For example, the deformed part 224 may have a form in which it is elongatedly extended from the lens supporting part 222 toward the upper housing 120. The number of deformed parts 224 may be provided in plural. For example, the number of deformed parts 224 may be four, as shown in FIG. 4. However, the number of deformed parts 224 is not limited to four. For example, the number of deformed parts 224 may be increased as long as it does not hinder the lens supporting parts 222 from stably supporting the lens 210. The deformed part 224 may be configured to be deformed by the piezoelectric member 230. For example, the deformed part 224 may be formed of a member that may be easily elastically deformed. For example, the deformed part 224 may be formed of a metal having excellent elastic deformation and restoration features. However, the material of the deformed parts 224 is not limited to the metal. Here, the deformed part 224 may also be formed of plastic or other materials. The deformed part 224 configured as described above may be warped upwardly (based on FIG. 4) or warped downwardly (based on FIG. 4) by driving force of the piezoelectric member 230 to change a relative position of the lens 210 to a lens 130 (See FIG. 3).

The piezoelectric member 230 may be configured to deform the support member 220. For example, the piezoelectric member 230 may be connected to the deformed part 224 of the support member 220 to apply force to the deformed part 224 in a direction in which the deformed part 224 is extended or apply force to the deformed part 224 in a direction in which the deformed part 224 is contracted.

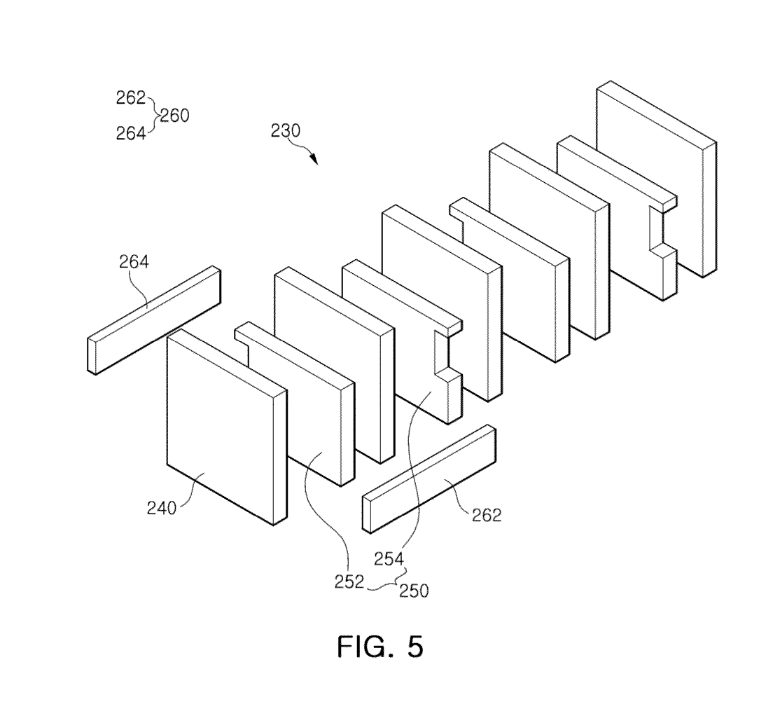

A configuration of the piezoelectric member will be described in detail with reference to FIG. 5.

The piezoelectric member 230 may include a piezoelectric element 240, an internal electrode 250, and an external electrode 260. For example, the piezoelectric member 230 may have a form in which a plurality of piezoelectric elements 240 and a plurality of internal electrodes 250 are alternately stacked and coupled to each other. In addition, the piezoelectric member 230 may have a form in which two or more external electrodes 260 are disposed on both side surfaces of the piezoelectric elements 240 and the internal electrodes 250.

The piezoelectric element 240 may be a plate member having a substantially rectangular shape. All of the plurality of piezoelectric elements 240 may have the same size and shape. For example, all of the plurality of piezoelectric elements 240 may be plate members having a rectangular shape. The plurality of piezoelectric elements 240 may be disposed at predetermined intervals. For example, the plurality of piezoelectric elements 240 may be disposed at predetermined intervals in a thickness direction.

The plurality of internal electrodes 252 and 254, collectively denoted by 250 may be disposed on one surface of the piezoelectric element 240. For example, the plurality of internal electrodes 252 and 254, collectively denoted by 250 may be interposed between the piezoelectric elements 240, respectively. The plurality of internal electrodes 252 and 254, collectively denoted by 250 may include first and second internal electrodes 252 and 254. For example, the first internal electrode 252 may be disposed so as to be biased toward a first side surface (to the right based on FIG. 5) of the piezoelectric element 240, and the second internal electrode 254 may be disposed so as to be biased toward a second side surface (to the left based on FIG. 5) of the piezoelectric element 240.

The external electrodes 260 may be disposed so as to contact the piezoelectric elements 240 and the internal electrodes 250. For example, the external electrodes 260 may be disposed so as to contact side surfaces of the piezoelectric elements 240 and side surfaces of the internal electrodes 250. The external electrode 260 may include first and second external electrodes 262 and 264. The first external electrode 262 may be disposed so as to contact the plurality of piezoelectric elements 240 and first internal electrodes 252. For example, the first external electrode 262 may be elongatedly formed on first side surfaces of the piezoelectric elements 240 and the internal electrodes 250 and may contact the plurality of piezoelectric elements 240 and first internal electrodes 252. The second external electrode 264 may be disposed so as to contact the plurality of piezoelectric elements 240 and second internal electrodes 254. For example, the second external electrode 264 may be elongatedly formed on second side surfaces of the piezoelectric elements 240 and the internal electrodes 250 and may contact the plurality of piezoelectric elements 240 and second internal electrodes 254.

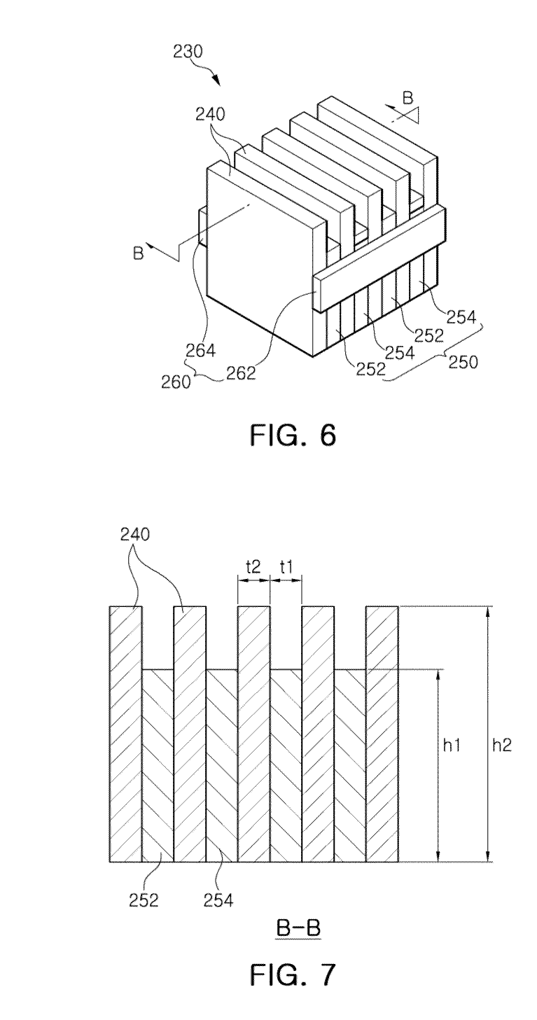

A coupling form of the piezoelectric member will be described with reference to FIG. 6.

The piezoelectric member 230 may have a structure in which the plurality of piezoelectric elements 240 and the plurality of internal electrodes 250 are alternately disposed in a single direction. In addition, the piezoelectric member 230 may have a structure in which a pair of external electrodes 260 are formed on both side surfaces of the stacked structure, respectively.

A cross-sectional form of the piezoelectric member will be described with reference to FIG. 7.

The piezoelectric member 230 may be configured so that an empty space is formed between the piezoelectric elements 240.

For example, the internal electrode 250 may have a height h1 lower than a height h2 of the piezoelectric element 240. Therefore, a space depending on a height difference between the internal electrode 250 and the piezoelectric element 240 may be formed between the piezoelectric elements 240. This space may improve a degree of freedom in deformation of the piezoelectric element 240. For reference, a thickness t1 of the internal electrode 250 and a thickness t2 of the piezoelectric element 240 may be the same as each other.

Since the piezoelectric member 230 configured as described above has a form in which the plurality of piezoelectric elements 240 are stacked, it may provide strong driving force. In addition, in the piezoelectric member 230 according to an exemplary embodiment of the present disclosure, since the degree of freedom in the deformation of the piezoelectric element 240 may be sufficiently secured by the space between the piezoelectric elements 240, sufficient driving force may be provided at the same voltage.

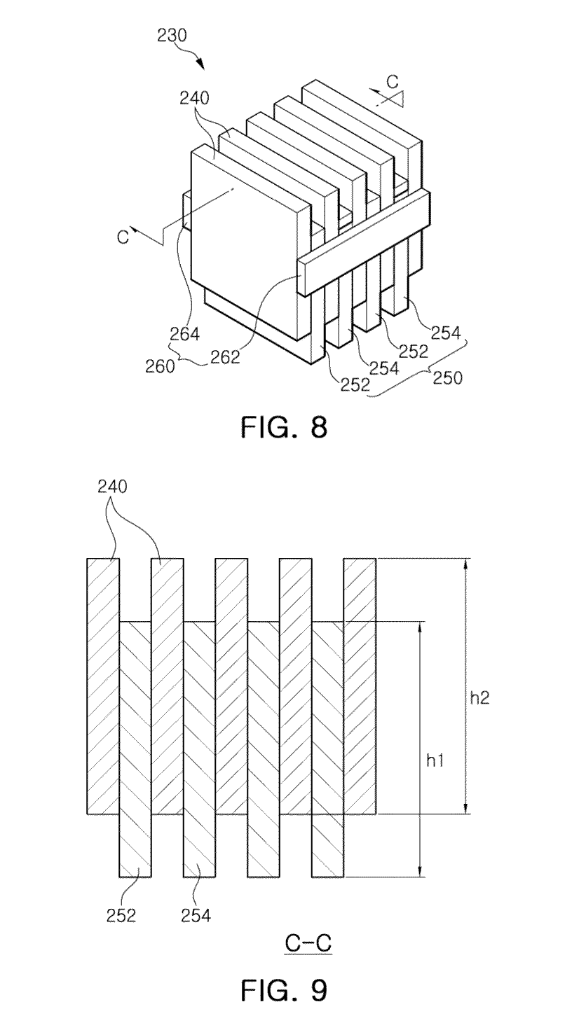

A piezoelectric member according to another form will be described with reference to FIGS. 8 and 9.

A piezoelectric member 230 according to another form may be different indisposition forms of piezoelectric elements 240 and internal electrodes 250 from the piezoelectric member according to the above-mentioned form. For example, the internal electrode 250 may be disposed so as to protrude toward one side (lower side based on FIG. 8) of the piezoelectric element 240. The piezoelectric member 230 according to another form may be configured so that the piezoelectric element 240 and the internal electrode 250 have the same size as each other. For example, the internal electrode 250 may have the same height h1 as a height h2 of the piezoelectric element 240 (See FIG. 9).

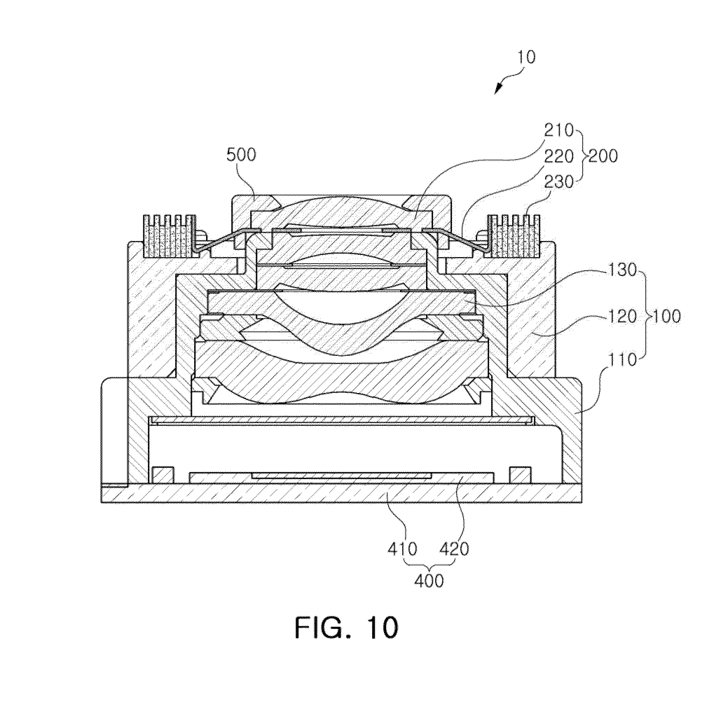

A cross-sectional form of the camera module will be described with reference to FIG. 10.

The camera module 10 may have a form in which the image sensor unit 400, the housing units 110 and 120, collectively denoted by 100, and the actuator unit 200 are sequentially coupled to each other in the optical axis direction. For example, the housing unit 100 may be mounted on an upper surface of the image sensor unit 400, and the actuator unit 200 may be mounted on an upper surface of the housing unit 100.

The camera module 10 may be configured so that one or more lens move in the optical axis direction. For example, the lens 210 of the actuator unit 200 may be moved upwardly or downwardly by the piezoelectric member 230 warpage-deforming the support member 220. Therefore, the camera module 10 may have a plurality of focal lengths, thereby implementing a clear image.

In the camera module 10 configured as described above, since the focal length is changed by moving only a small number of lenses, an automatic focal length adjusting time may be shortened, and a current consumption amount required for driving the actuator unit 200 may be significantly decreased.

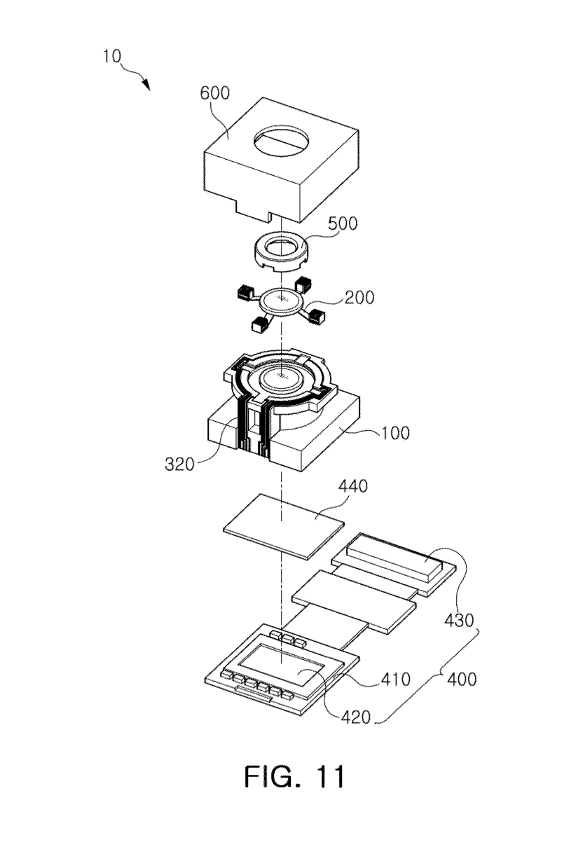

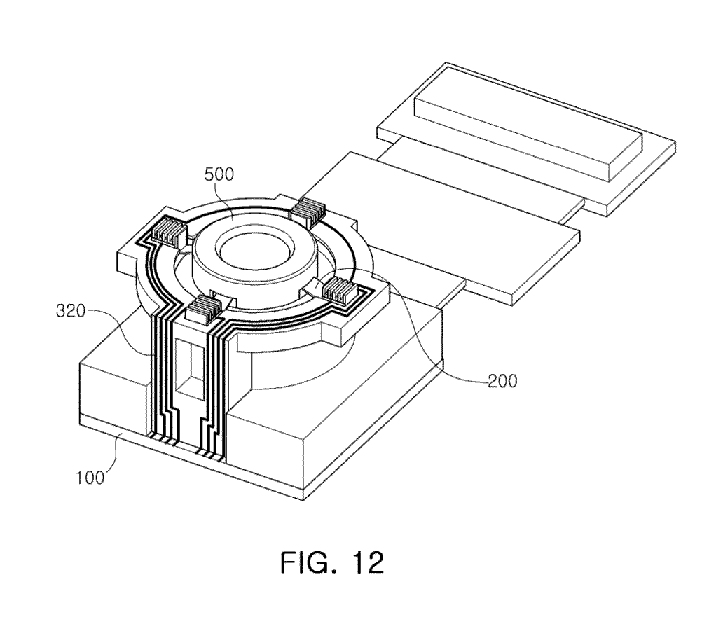

Next, a camera module according to another exemplary embodiment of the present disclosure will be described with reference to FIG. 11. For reference, in the following description, components the same as those of the camera module according to an exemplary embodiment of the present disclosure described above will be denoted by the same reference numerals and a description thereof will be omitted.

The camera module 10 according to the present exemplary embodiment may be different from the camera module in terms of a shape of a connecting unit 400, according to an exemplary embodiment of the present disclosure described above. For example, the connecting unit 400 may be formed integrally with the housing unit 100. The camera module 10 according to the present exemplary embodiment may include a housing unit 100 in which lower and upper housings are integrated with each other. For example, the housing unit 100 may be formed of one member that is not separated. The camera module 10 according to the present exemplary embodiment may include an infrared cut-off filter 440 filtering infrared light. For example, the infrared cut-off filter 440 may be interposed between the housing unit 100 and the image sensor unit 400.

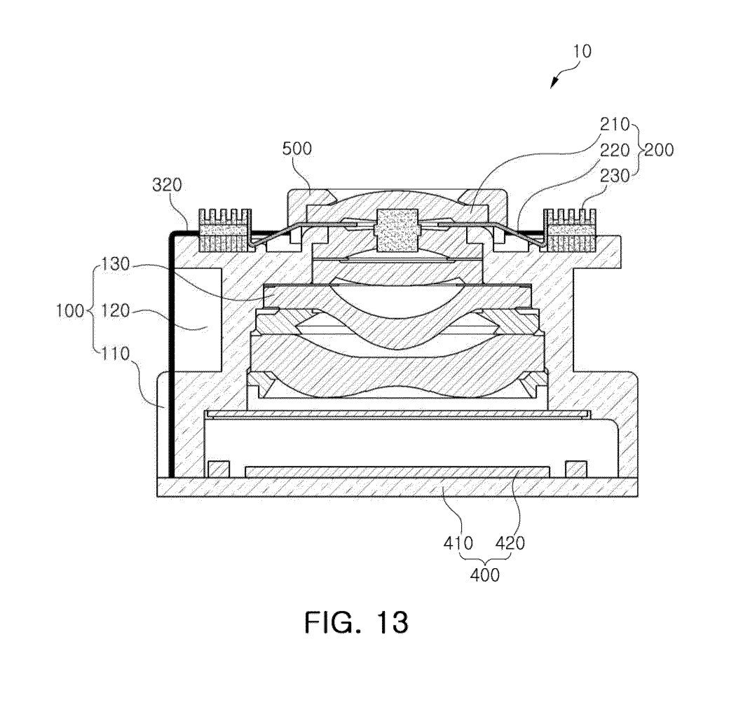

The camera module in a state in which the shield can is removed will be described with reference to FIGS. 12 and 13.

The camera module 10 may include the housing unit 100 on which circuit patterns 320 are formed. For example, the housing unit 100 may have the circuit patterns 320 formed on a surface thereof in order to connect the actuator unit 200 and the image sensor unit 400 to each other. The housing unit 100 may be a molded interconnection device (MID) component. For example, the housing unit 100 may be a component molded integrally with a conductive circuit.

In the camera module 10 formed as described above, since a process of connecting the actuator unit 200 and the image sensor unit 400 to each other may be omitted, the camera module 10 may be easily manufactured, and a cost required for manufacturing the camera module 10 may be decreased.

As set forth above, according to exemplary embodiments of the present disclosure, driving reliability of the lens and an assembly feature of the camera module may be improved.

While exemplary embodiments have been shown and described above, it will be apparent to those skilled in the art that modifications and variations could be made without departing from the scope of the present invention as defined by the appended claims.

What is claimed is:

1. An actuator unit comprising:
a support member supporting a first lens so that the first lens is maintained in a non-contact state with a second lens adjacent thereto; and
a piezoelectric member connected to the support member, deforming the support member so that the lenses are movable in an optical axis direction, and including a plurality of piezoelectric elements and a plurality of internal electrodes.

2. The actuator unit of claim 1, wherein the piezoelectric member includes:
the plurality of piezoelectric elements having a first size;
the plurality of internal electrodes disposed between the plurality of piezoelectric elements and having a second size; and
a plurality of external electrodes disposed on side surfaces of the piezoelectric elements.

3. The actuator unit of claim 1, wherein the plurality of piezoelectric elements are arranged in a direction perpendicular to the optical axis direction of the lens.

4. The actuator unit of claim 1, wherein the plurality of piezoelectric elements have a size different from that of the plurality of internal electrodes.

5. The actuator unit of claim 1, wherein the plurality of internal electrodes are disposed so as to be misaligned with the plurality of piezoelectric elements so that intervals are formed between the plurality of piezoelectric elements disposed in a single direction.

6. A camera module comprising:
a housing unit accommodating a plurality of lenses therein;
an actuator unit coupled to the housing unit and configured to move the lenses in an optical axis direction; and
a connecting unit formed on the housing unit and connecting the actuator unit and an image sensor unit to each other.

7. The camera module of claim 6, wherein the actuator unit includes:
a support member connected to the lens; and
a piezoelectric member configured to deform the support member.

8. The camera module of claim 6, wherein the actuator unit includes:
a plurality of piezoelectric elements having a first size;
a plurality of internal electrodes having a second size and interposed between the piezoelectric elements, respectively; and
a plurality of external electrodes disposed on side surfaces of the piezoelectric elements.

9. The camera module of claim 6, wherein the connecting unit is a flexible printed circuit board disposed on an outer surface of the housing unit.

10. The camera module of claim 6, wherein the connecting unit includes circuit patterns formed integrally with the housing unit.
